(19) United States
(12) Patent Application Publication
(10) Pub. No.: US 2007/0007656 A1
(43) Pub. Date: Jan. 11, 2007

(54) Semiconductor device and methods thereof

(75) Inventor: Kuk-Han Yoon, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/476,796

(22) Filed: Jun. 29, 2006

(30) Foreign Application Priority Data
Jul. 11, 2005 (KR) 2005-62145

(51) Int. Cl. H01L 23/52; H01L 21/4763

(52) U.S. Cl. 257/758; 438/639; 438/622; 257/760

(57) ABSTRACT

An insulation interlayer having first contact holes exposing first contact pads is formed on a semiconductor structure having the first and second contact pads. Conductive patterns connected to the first contact pads through the first contact holes are formed on the insulation interlayer. Insulation layer patterns are formed on the insulation interlayer and the conductive patterns. The conductive patterns and the insulation layer patterns extend in different directions. Portions of the insulation layers, exposed between the conductive patterns and the insulation layer patterns, are etched to form second contact holes exposing the second contact pads. Capping patterns are formed on portions of the insulation layer patterns, exposed between the insulation layer patterns, and side faces of the second contact holes. Contact plugs electrically connected to the second contact pads are formed between the capping patterns and the contact plugs.

### PRIORITY STATEMENT

This application claims benefit of priority under 35 U.S.C. § 119 from Korean Patent Application No. 2005-62145 filed on Jul. 11, 2005, the disclosure of which is incorporated herein by reference in its entirety.

### BACKGROUND OF THE INVENTION

1. Field of the Invention

Example embodiments are directed generally to a semiconductor device and methods thereof, and more particularly to a semiconductor device and methods of fabricating a semiconductor device.

2. Description of the Related Art

A semiconductor device manufacturing process may include repeatedly performing a series of processes on a semiconductor substrate such as a silicon wafer. For example, a deposition process may be performed to form a layer on the semiconductor substrate. An oxidation process may be performed to form an oxide layer on the semiconductor substrate and/or to oxidize one or more layers formed on the semiconductor substrate. A photolithography process may be performed to form a photoresist pattern. A planarization process may be performed to planarize one or more layers present on the semiconductor substrate.

Modern semiconductor devices may be highly integrated such that a size of a unit cell of the semiconductor device may be reduced. Thus, line widths of conductive patterns such as word lines or bit lines may likewise be reduced and aspect ratios of contact holes formed between the conductive patterns may be increased.

FIGS. 1 and 2 are cross-sectional views and FIG. 3 is a plan view illustrating a process of manufacturing a conventional semiconductor device. The cross-sectional view of FIG. 1 illustrates an example cross-sectional view taken along a bit line of the conventional semiconductor device. The example cross-sectional view of FIG. 2 illustrates a cross-sectional view taken along a word line of the conventional semiconductor device. FIG. 3 illustrates an example plan view of a bit line structure of FIG. 2.

Referring to FIGS. 1 to 3, an isolation layer 12 may be formed at an upper portion of a semiconductor substrate 10 to define active regions 14. Gate structures 22 including gate insulation layer patterns 16, gate electrodes 18, gate mask patterns 20 and gate spacers 22 may be formed on the active regions 14. In an example, the gate electrode 18 may correspond to a word line.

Referring to FIGS. 1 to 3, first impurity regions 26 and second impurity regions 28 may be formed at surface portions of the active region 14, the surface portions being adjacent to the gate structures 24. The first impurity region 26 and the second impurity regions 28 may correspond to source/drain regions. A first insulation interlayer 30 covering the gate structures 24 may be formed. The gate structures 24 formed on the semiconductor substrate 10 may extend in a first direction such that the gate structures 24 may collectively have a “striped” shape.

Referring to FIGS. 1 to 3, the first insulation interlayer 30 may be planarized until the gate structures 24 are exposed. First contact pads 32 and second contact pads 34 electrically connected to the first impurity regions 26 and the second impurity regions 28, respectively, may be formed.

Referring to FIGS. 1 to 3, a second insulation interlayer 36 may be formed on the gate structures 24, the first contact pads 32 and the second contact pads 34. Bit line structures 46 including metal barrier layer patterns 38, bit lines 40, bit line mask patterns 42 and bit line spacers 44 may be formed on the second insulation interlayer 36. The bit line structures 46 formed on the second insulation interlayer 36 may extend in a second direction substantially perpendicular to the first direction such that the bit line structures 46 may collectively have a “striped” shape. The bit lines structures 46 may be electrically connected to the first contact pads 32 through the second insulation interlayer 36.

Referring to FIGS. 1 to 3, a third insulation interlayer 48 filling up spaces positioned between the bit line structures 46 may be formed. The third insulation interlayer 48 and the second insulation interlayer 36 may be etched to form storage node contact holes (not shown) exposing the second contact pads 34.

Referring to FIGS. 1 to 3, the bit line structures 46 may have a lower line width and a higher height. Accordingly, an aspect ratio of the spaces between the bit line structures 46 may be higher. Voids 50 may be formed during the formation of the third insulation interlayer 48. The voids 50 may generally extend in the first direction. Adjacent storage node contact holes (not shown) may communicate with each other via the voids 50 while the contact holes are formed.

In addition, storage node contact plugs (not shown) formed in the storage node contact holes may be electrically connected to one another via the voids 50 while the storage node contact plugs are formed. Further, bridges (e.g., electrical connections) may be generated between capacitors (not shown) in the conventional semiconductor device. The electrical interconnection of elements via the voids 50 may degrade performance characteristics associated with the conventional semiconductor device.

### SUMMARY OF THE INVENTION

An example embodiment of the present invention is directed to a semiconductor device, including a semiconductor structure including first contact pads and second contact pads, an insulation interlayer formed on the semiconductor structure, the insulation interlayer including first contact holes exposing the first contact pads and second contact holes exposing the second contact pads, conductive patterns formed on the first insulation interlayer, the conductive patterns extending in a first direction and being electrically connected to the first pads through the first contact holes, insulation layer patterns formed on an upper face of the insulation interlayer and the conductive patterns, the insulation layer patterns extending in a second direction other than the first direction, capping patterns formed on portions of the conductive patterns and side faces of the second contact holes, the portions being positioned between the insulation layer patterns and contact plugs formed between the capping patterns, the contact plugs being electrically connected to the second contact pads.

Another example embodiment of the present invention is directed to a method of manufacturing a semiconductor device, including forming a semiconductor structure including first contact pads and second contact pads, forming an insulation interlayer on the semiconductor structure, the insulation interlayer including first contact holes exposing the first contact pads, forming conductive patterns on the insulation interlayer, the conductive patterns extending in a first direction and being electrically connected to the first contact pads through the first contact holes, forming insulation layer patterns on an upper face of the insulation interlayer and the conductive patterns, the insulation layer patterns extending in a second direction other than the first direction, anisotropically etching first portions of the insulation layers to form second contact holes exposing the second contact pads, the first portions being exposed between the conductive patterns and the insulation layer patterns, forming capping patterns on second portions of the insulation layer patterns and side faces of the second contact holes, the second portions being exposed between the insulation layer patterns and forming contact plugs between the capping patterns, the contact plugs electrically connected to the second contact pads.

Another example embodiment of the present invention is directed to a method of manufacturing a semiconductor device, including forming a plurality of bit lines, forming a capping layer on the plurality of bit lines, the capping layer selectively including at least one void between adjacent bit lines of the plurality of bit lines and removing a portion of the capping layer, the removed portion including the at least one void.

Another example embodiment of the present invention is directed to a method of manufacturing a semiconductor device, including forming a plurality of bit lines based on a plurality of bit mask patterns and removing, at least in part, the plurality of bit mask patterns after forming the plurality of bit lines.

Another example embodiment of the present invention is directed to a semiconductor having contact plugs electrically insulated from one another.

### BRIEF DESCRIPTION OF THE DRAWINGS

The accompanying drawings are included to provide a further understanding of example embodiments of the invention, and are incorporated in and constitute a part of this specification. The drawings illustrate example embodiments of the present invention and, together with the description, serve to explain principles of the present invention.

FIGS. 1 and 2 are cross-sectional views and FIG. 3 is a plan view illustrating a process of manufacturing a conventional semiconductor device.

FIGS. 4 to 11 and FIGS. 13 to 18 are cross-sectional views and FIG. 12 is a plan view illustrating processes for manufacturing a semiconductor device according to an example embodiment of the present invention.

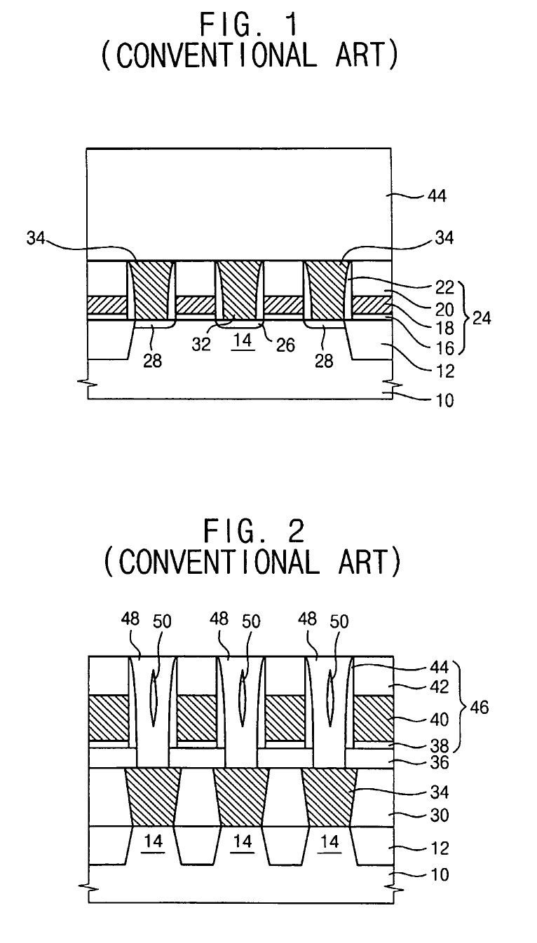

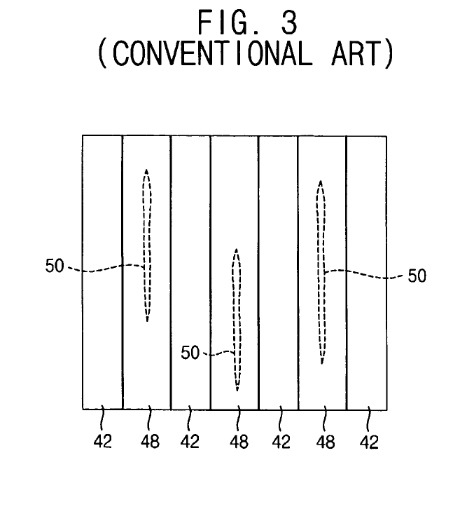

### DETAILED DESCRIPTION OF EXAMPLE EMBODIMENTS OF THE PRESENT INVENTION

Example embodiments of the present invention will be described with reference to the accompanying drawings. The present invention may, however, be embodied in many different forms and should not be construed as limited to the example embodiments set forth herein. Rather, the example embodiments are provided so that disclosure of the present invention will be thorough and complete, and will fully convey the scope of the present invention to those skilled in the art. The principles and features of this invention may be employed in varied and numerous embodiments without departing from the scope of the present invention. In the drawings, the size and relative sizes of layers and regions may be exaggerated for clarity. The drawings are not to scale. Like reference numerals refer to like elements throughout.

It will be understood that when an element or layer is referred to as being “on”, “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present. As used herein, the term “and/or” may include any and all combinations of one or more of the associated listed items.

It will be understood that, although the terms first, second, etc. may be used herein to describe various elements, components, regions, layers and/or sections. These elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Example embodiments of the present invention may be below described with reference to cross-section illustrations that are schematic illustrations of idealized embodiments of the present invention. As such, variations from the shapes of the illustrations as a result, for example, of manufacturing techniques and/or tolerances, may be expected. Thus, example embodiments of the present invention should not be construed as limited to the particular shapes of regions illustrated herein but are to include deviations in shapes that result, for example, from manufacturing. For example, an etched region illustrated as a rectangle may have rounded or curved features. Thus, the regions illustrated in the figures are schematic in nature of a device and are not intended to limit the scope of the present invention.

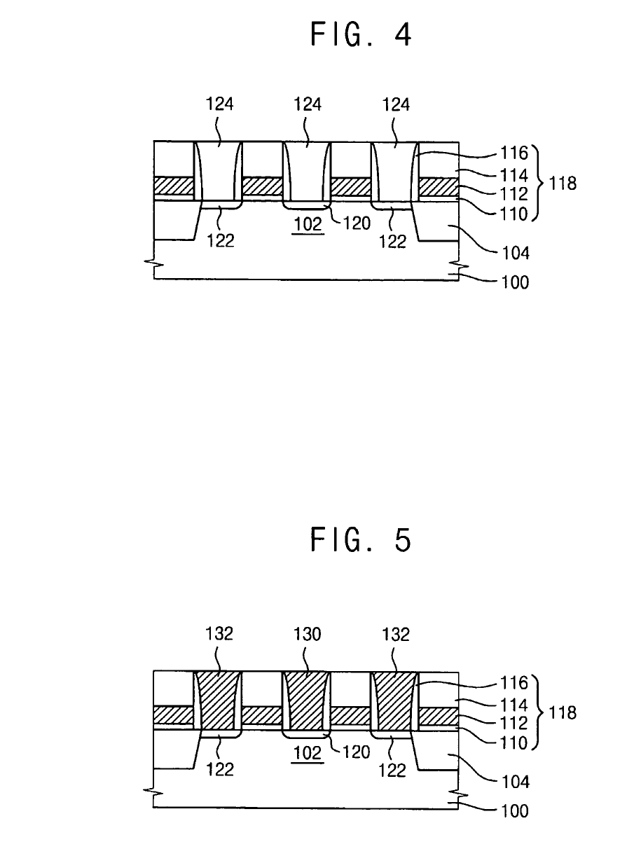

FIGS. 4 to 11 and FIGS. 13 to 18 are cross-sectional views and FIG. 12 is a plan view illustrating processes for manufacturing a semiconductor device according to an example embodiment of the present invention.

FIG. 4 is a cross-sectional view illustrating a transistor formed on a semiconductor substrate 100 according to example embodiments of the present invention.

In the example embodiment of FIG. 4, an isolation layer 104 may be formed at an upper portion of the semiconductor substrate 100 (e.g., a silicon wafer) to define active regions 102. The isolation layer 104 may be formed by a shallow trench isolation (STI) process. The isolation layer 104 may electrically insulate the active regions 102 from one another.

In the example embodiment of FIG. 4, a gate insulation layer having a relatively thin thickness may be formed on the active regions 102 and the isolation layer 104. In an example, a silicon oxide layer may be used as the gate insulation layer. The silicon oxide layer may be formed by a thermal oxidation process and/or a chemical vapor deposition (CVD) process.

In the example embodiment of FIG. 4, a first conductive layer and a first mask film may be successively formed on the gate insulation layer. The first conductive layer and the first mask film may operate as a gate conductive layer and a gate mask film, respectively. In an example, a poly-silicon layer doped with impurities may be used as the gate conductive layer. A metal silicide layer may be further formed on the poly-silicon layer doped with the impurities. The first mask film may include material with an etching selectivity with respect to a first insulation interlayer 124. For example, if the first insulation interlayer 124 includes silicon oxide, the first mask film may include silicon nitride.

In the example embodiment of FIG. 4, first photoresist patterns may be formed on the first mask film. The first mask film, the first conductive layer and the gate insulation layer may be successively etched using the first photoresist patterns as an etch mask such that gate insulation layer patterns 110, gate electrodes 112 and gate mask patterns 114 may be formed on the semiconductor substrate 100. In an example, the gate electrodes 112 may correspond to word lines.

In the example embodiment of FIG. 4, the first photoresist patterns may be removed by an ashing process and/or a strip process. In an alternative example, the first mask film may be anisotropically etched using the first photoresist patterns as a first etch mask such that the gate mask patterns 114 may be formed on the first conductive layer. The first photoresist patterns may then be removed. Thereafter, the first conductive layer and the gate insulation layer may be anisotropically etched using the gate mask patterns 114 as a second etch mask such that the gate electrodes 112 and the gate insulation layer patterns 110 may be formed.

In the example embodiment of FIG. 4, a spacer layer may be formed on the semiconductor substrate 100 to cover the gate mask patterns 114, the gate electrodes 112 and the gate insulation layer patterns 110. The spacer layer may be anisotropically etched such that gate spacers 116 may be formed on side faces of the gate mask patterns 114, the gate electrodes 112 and the gate insulation layer patterns 110. Gate structures 118 extending in a first direction may thereby be formed on the semiconductor substrate 100. In an example, the gate structures 118 may collectively have a “striped” shape. That is, each of the gate structures 118 has a substantially bar-like shape.

In the example embodiment of FIG. 4, first impurity regions 120 and second impurity regions 122 may be formed at surface portions of the active regions 102, the surface portions being exposed between the gate structures 118, such that transistors 124 may be manufactured on the semiconductor substrate 100. The first impurity regions 120 and the second impurity regions 122 may be used as source/drain regions. In an example, two transistors 124 may be formed on respective active regions 102. The first impurity region 120 may be provided between the two transistors 124 such that the two transistors 124 may share the first impurity regions 120.

In the example embodiment of FIG. 4, the first impurity region 120 may include a first lower concentration impurity area and a first higher concentration impurity area enclosed within the first lower concentration impurity area. The second impurity region 122 may include a second lower concentration impurity area and a second higher concentration impurity region enclosed within the second higher concentration impurity area. In an example, the first and second lower concentration impurity areas may be formed before the gate spacer 116 is formed. In a further example, the first and second higher concentration impurity areas may be formed after the gate spacer 116 is formed.

In the example embodiment of FIG. 4, the first insulation interlayer 124 may be formed on the semiconductor substrate 100 on which the gate structures 118 may be formed. In an example, the first insulation interlayer 124 may include silicon oxide. A space or gap between the gate structures 118 may be filled with the first insulation layer. The first insulation interlayer 124 may be planarized by a planarizing process (e.g., by a chemical mechanical polishing (CMP) process) until the gate mask patterns 114 are exposed.

FIG. 5 is a cross-sectional view illustrating first and second contact pads 130 and 132 formed on the first and second impurity regions 120 and 122, respectively, according to another example embodiment of the present invention.

In the example embodiment of FIG. 5, after the first insulation interlayer 124 is planarized, second photoresist patterns may be formed on the first insulation interlayer 124. The first insulation interlayer 124 may be anisotropically etched using the second photoresist patterns as an etch mask such that first and second contact holes exposing the first and second impurity regions 120 and 122, respectively, may be formed through the first insulation interlayer 124. During the anisotropic etching of the first insulation interlayer 124, the gate spacers 116 may guide the first and second contact holes toward the first and second impurity regions 120 and 122, respectively. The gate spacers 116 may include a material having an etching selectivity with respect to the first insulation interlayer 124. During the anisotropic etching of the first insulation interlayer 124, the gate mask patterns 114 and the gate spacers 116 may protect the gate electrodes 112.

In the example embodiment of FIG. 5, after the anisotropic etching of the first insulation interlayer 124, the second photoresist patterns may be removed. A second conductive layer may be formed on the first insulation interlayer 124 and the gate mask patterns 114 to fill up the first and second contact holes. In an example, the second conductive layer may include polysilicon doped with impurities. In an alternative example, the second conductive layer may include metal nitride (e.g., titanium nitride). In another alternative example, the second conductive layer may include metal (e.g., tungsten).

In the example embodiment of FIG. 5, a surface portion of the second conductive layer may be removed until the gate mask patterns 114 are exposed such that first contact pads 130 and second contact pads 132 may be formed in the first and second contact holes, respectively. The first contact pads 130 and second contact pads 132 may be electrically connected to the first impurity regions 120 and the second impurities regions 122, respectively. The surface portion of the second conductive layer may be removed by an etch-back process and/or a CMP process.

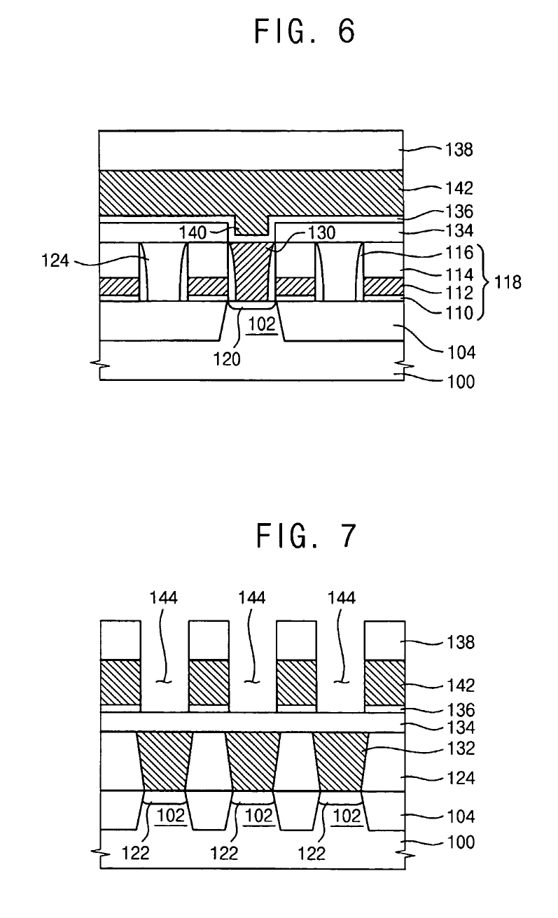

FIGS. 6 and 7 are cross-sectional views illustrating bit lines electrically connected to the first contact pads 130 according to another example embodiment of the present invention.

In the example embodiment of FIGS. 6 and 7, after the first and second contact pads 130 and 132 are formed, a second insulation interlayer 134 may be formed on the first and second contact pads 130 and 132, the gate mask patterns 114 and the first insulation interlayer 124. In an example, the second insulation interlayer 134 may include substantially the same material as the first insulation interlayer 124. The second insulation interlayer 134 may insulate the gate structures 118 from bit lines 142.

In the example embodiment of FIGS. 6 and 7, third photoresist patterns may be formed on the second insulation interlayer 134. The second insulation interlayer may thereafter be anisotropically etched using the third photoresist patterns as an etch mask such that bit line contact holes exposing the first contact pads 130 may be formed.

In the example embodiment of FIGS. 6 and 7, the third photoresist patterns may be removed after the bit line contact holes are formed. A metal barrier layer 136 may be formed on inner faces of the bit line contact holes and an upper face of the second insulation interlayer 134. A third conductive layer may be formed on the metal barrier layer 136 such that the bit line contact holes (e.g., which may be partially filled with the metal barrier layer 136) may become more fully filled with the third conductive layer. A second mask film may be formed on the third conductive layer. The second mask film may include a material having an etching selectivity with respect to the second insulation interlayer. In an example, the second mask film may include silicon nitride.

In the example embodiment of FIGS. 6 and 7, the metal barrier layer 136 may include a metal film and/or a metal nitride film. The third conductive layer may include metal (e.g., tungsten). In a further example, the metal barrier layer 136 may include a titanium film and/or a titanium nitride film. The titanium film may operate as an ohmic film capable of reducing an ohmic resistance.

In the example embodiment of FIGS. 6 and 7, fourth photoresist patterns may be formed on the second mask film. The second mask film may be etched using the fourth photoresist patterns as an etch mask such that bit line mask patterns 138 may be formed on the third conductive layer. The bit line mask patterns 138 may extend in a second direction substantially perpendicular to the first direction. In an example, the bit line mask patterns 138 may have a “striped” shape. That is, each of the bit line mask patterns 138 has a substantially bar-like shape.

In the example embodiment of FIGS. 6 and 7, the fourth photoresist pattern is removed. Thereafter, the third conductive layer and the metal barrier layer 136 may be etched using the bit line mask patterns 138 as an etch mask such that bit lines 142 may be formed. Bit line contact plugs 140 may be electrically connected between the bit lines 142 and the first contact pads 130.

In the example embodiment of FIGS. 6 and 7, after the bit lines 142 are formed, the bit line mask patterns 138 may be removed. In an example, the bit line mask patterns 138 may be removed using an etching solution including phosphoric acid. The bit line mask patterns 138 may be removed in order to reduce aspect ratios of spaces 144 between the bit lines 142.

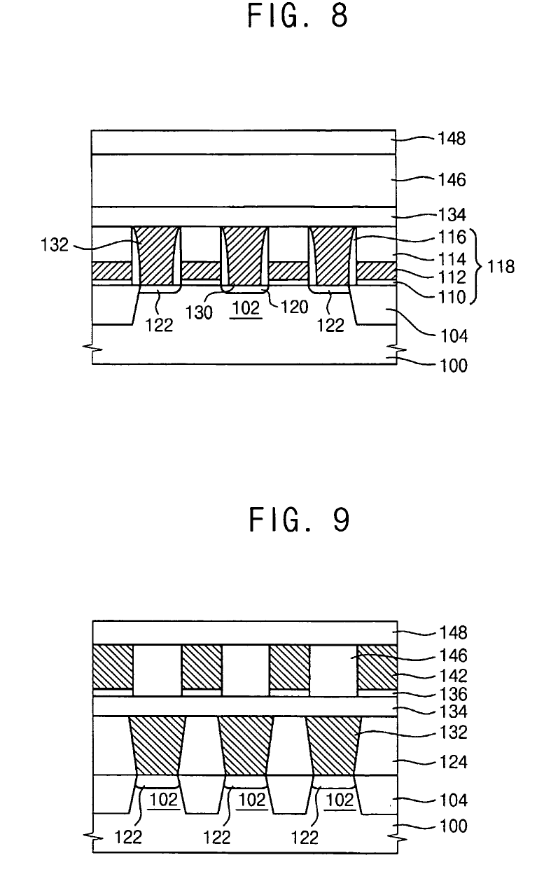

FIGS. 8 and 9 are cross-sectional views illustrating third and fourth insulation layers 146 and 148 according to another example embodiment of the present invention.

In the example embodiment of FIGS. 8 and 9, the third insulation interlayer 146 may be formed so as to fill (e.g., at least partially) the spaces 144 between the bit lines 142. The third insulation interlayer 146 may be planarized until the bit lines 142 are exposed. In an example, the third insulation interlayer 146 may be planarized by a CMP process.

As described above with respect to the example embodiment of FIGS. 6 and 7, the bit line mask patterns 138 may be removed before the third insulation interlayer 146 is formed. Further, bit line spacers may not be formed on side faces of the bit lines 142. Thus, the aspect ratios of the spaces 144 between the bit lines 142 may be relatively small. As a result, the third insulation layer 146 of the example embodiment of FIG. 8 may fill (e.g., at least partially) the spaces 144 such that fewer voids or gaps may be generated in the spaces 144.

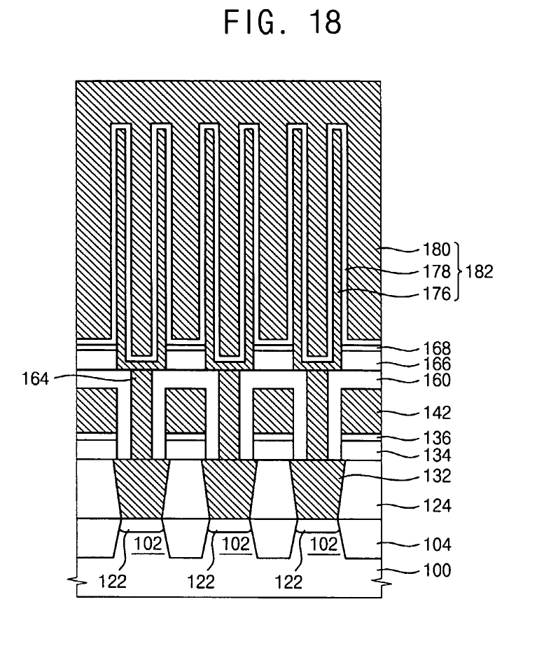

In the example embodiment of FIGS. 8 and 9, the fourth insulation interlayer 148 may be formed on the third insulation interlayer 146 and the bit lines 142. The fourth insulation interlayer 148 may electrically insulate the bit lines 142 from capacitors 182, as will be discussed in further detail later with respect to the example embodiment of FIG. 18.

In the example embodiment of FIGS. 8 and 9, the third insulation interlayer 146 and the fourth insulation interlayer 148 may include substantially the same material as the second insulation interlayer 134.

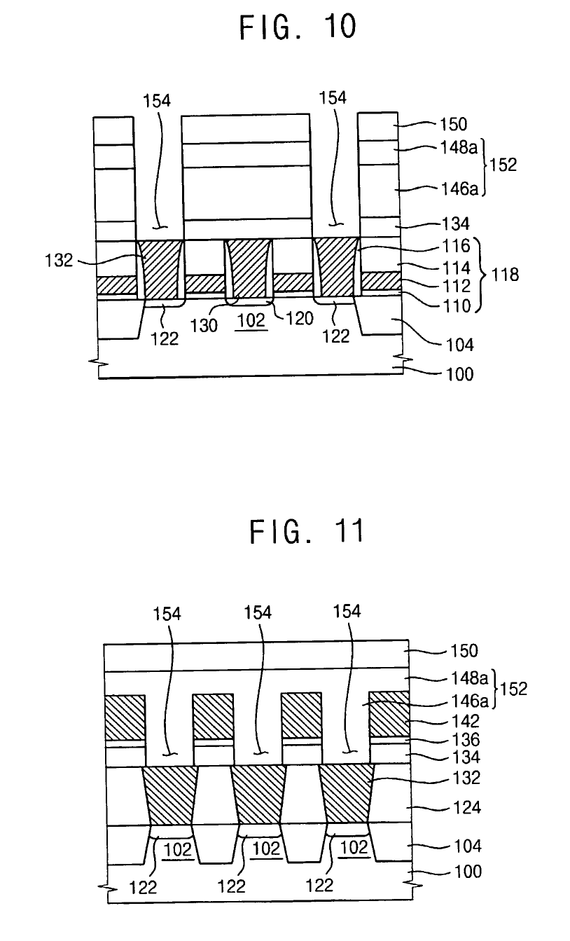

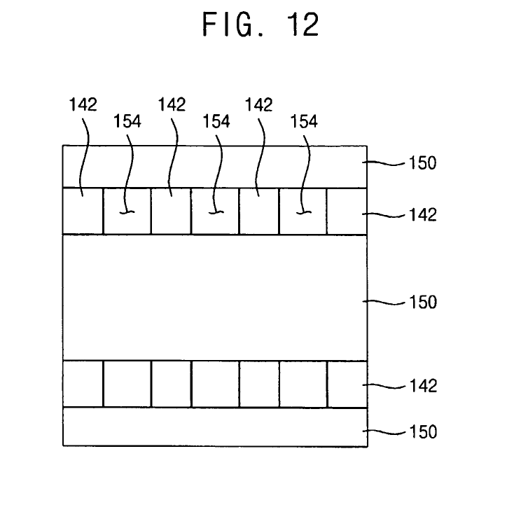

FIGS. 10 and 11 are cross-sectional views and FIG. 12 is a plan view illustrating third and fourth insulation interlayer patterns 146a and 148a according to another example embodiment of the present invention.

In the example embodiment of FIGS. 10 to 12, after the fourth insulation interlayer 148 is formed, mask patterns 150 may be formed on the fourth insulation interlayer 148. The mask patterns 150 may extend in a third direction (e.g., different than the second direction). In an example, the third direction may be substantially the same as the first direction. The mask patterns 150 may have a “striped” shape oriented along the third direction. In an example, the mask patterns 150 may include a photoresist composition and may be formed by a photolithography process.

In the example embodiment of FIGS. 10 to 12, the fourth insulation interlayer 148 and the third insulation interlayer 146 may be anisotropically etched using the mask patterns 150 as an etch mask such that insulation layer patterns 152 including the third insulation interlayer patterns 146a and the fourth insulation interlayer patterns 148a may be formed. The insulation layer patterns 152 may extend in the third direction. The second insulation interlayer 134 (e.g., partially exposed by the insulation layer patterns 152) may be anisotropically etched such that preliminary contact holes 154 (e.g., partially exposing the second contact pads 132) may be formed. The preliminary contact holes 154 may be guided toward the second contact pads 132 based on an etch rate difference between the bit lines 142 and the second, third and fourth insulation interlayers 134, 146 and 148.

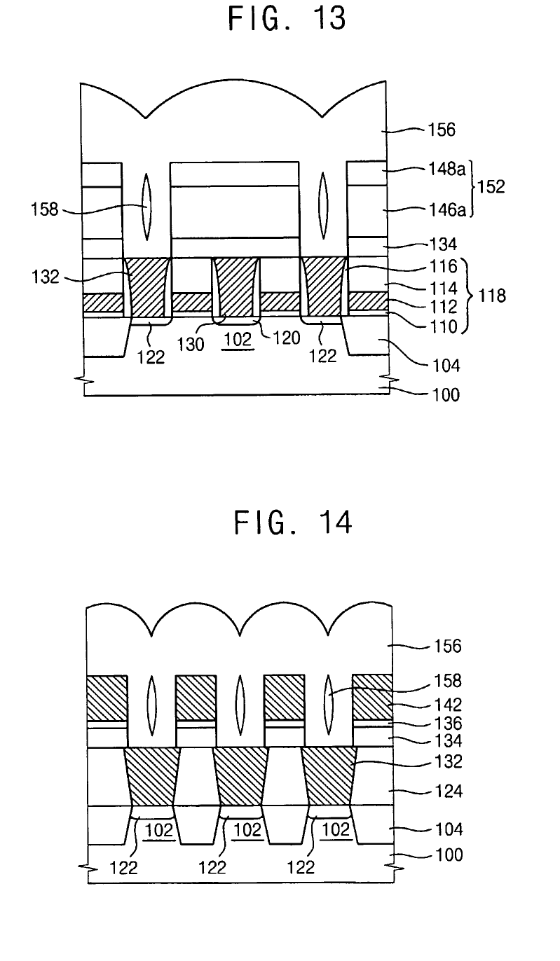

FIGS. 13 and 14 are cross-sectional views illustrating a capping layer 156 formed on the bit lines in FIG. 12 according to another example embodiment of the present invention.

In the example embodiment of FIGS. 13 and 14, after the preliminary contact holes 154 are formed, the mask patterns 150 may be removed by an ashing process and/or a strip process. The capping layer 156 may be formed on the contact pads 132, side faces of the preliminary contact holes 154, the insulation layer patterns 152 and exposed portions of the bit lines 142, the exposed portions being exposed between the insulation layer patterns 152.

In the example embodiment of FIGS. 13 and 14, the capping layer 156 may include a material having relatively poor step coverage such that voids 158 may be formed in the preliminary contact holes 154 and in spaces between the bit lines 142 and the insulation patterns 152. In an example, the material having the relatively poor step coverage may include tetraethyl orthosilicate (TEOS) and/or undoped silicate glass (USG). In a further example, the material having the relatively poor step coverage may include silicon oxide (e.g., obtained by a high density plasma chemical vapor deposition (HDP-CVD) process and/or a plasma enhanced chemical vapor deposition (PECVD) process).

In the example embodiment of FIGS. 13 and 14, a surface portion of the capping layer 156 may include “pitted” portions formed by the bit lines 142 and the insulation layer patterns 152. The pitted portions may be generally aligned with respective voids 158.

FIG. 15 is a cross-sectional view illustrating capping patterns 160 according to another example embodiment of the present invention.

In the example embodiment of FIG. 15, an etch-back process may be performed on the capping layer 156 to at least partially open or expose the voids 158. The etch-back process may be performed at least until the second contact pads 132 are exposed to form the capping patterns 160 enclosing the bit lines 142. Further, storage node contact holes 162 may be vertically formed between the capping patterns 160. The second contact pads 132 may be exposed through the storage node contact holes 162.

In an example, referring to FIG. 15, the etch-back process may be performed using an etching gas including fluoride. The capping layer 156 may be anisotropically etched by the etch-back process such that side faces of the bit lines 142 may not be exposed.

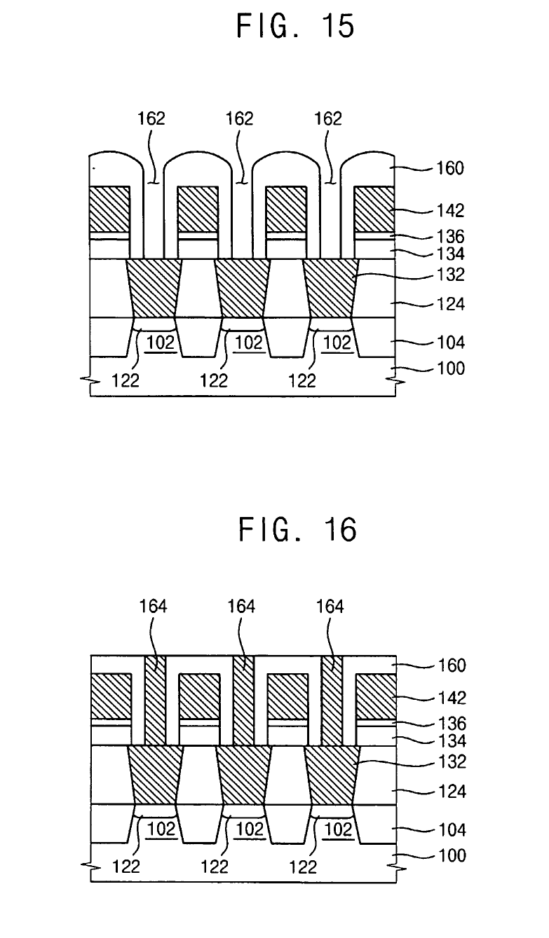

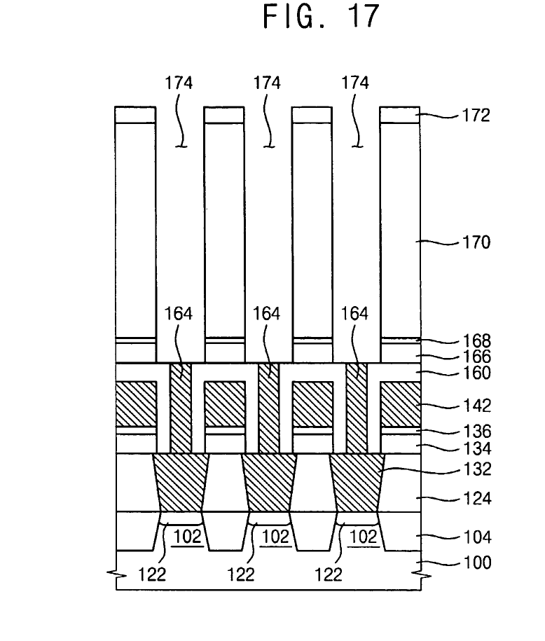

FIG. 16 is a cross-sectional view illustrating a storage node contact plug 164 formed in the storage node contact hole 162 according to another example embodiment of the present invention.

In the example embodiment of FIG. 16, a fourth conductive layer may be formed to fill (e.g., at least partially) the storage node contact hole 162. In an example, the fourth conductive layer may include polysilicon doped with impurities. The capping patterns 160 may electrically insulate the bit lines 142 from the fourth conductive layer.

In the example embodiment of FIG. 16, an upper portion of the fourth conductive layer may be removed such that storage node contact plugs 164 may be formed in the storage node contact holes 162. The fourth conductive layer and the capping patterns may be planarized (e.g., by a CMP process) such that the storage node contact plugs 164 may be obtained.

As described above, fewer voids may be formed in the third insulation layer 146 which may fill (e.g., at least partially) the spaces 144 between the bit lines 142. Therefore, fewer bridges (e.g., electrical interconnections) between the storage node contact plugs 164 may be formed. In a further example, unlike conventional bit line spacers including silicon nitride, the capping patterns 160 may include silicon oxide. Thus, a parasitic capacitance may be reduced (e.g., prevented) between the bit lines 142 and the storage node contact plugs 164.

FIG. 17 is a cross-sectional view illustrating a mold layer having openings exposing the storage node contact plugs 162 of FIG. 16 according to another example embodiment of the present invention.

In the example embodiment of FIG. 17, a fifth insulation interlayer 166 may be formed on the storage node contact plugs 164 and the capping patterns 160. The fifth insulation interlayer 166 may be provided between the bit lines 142 and storage node electrodes 176 (e.g., as will be described later in more detail with respect to FIG. 18) of capacitors 182 (e.g., as will be described later in more detail with respect to FIG. 18) such that the fifth insulation interlayer 166 may electrically insulate the bit lines 142 from the storage node electrodes 176 of the capacitors 182. In an example, the fifth insulation interlayer 166 may include a material substantially the same as that included in the fourth insulation interlayer 148.

In the example embodiment of FIG. 17, an etch stop layer 168 may be formed on the fifth insulation interlayer 166. The etch stop layer 168 may include a material having an etching selectivity with respect to a mold layer 170. In an example, the etch stop layer 168 may include silicon nitride.

In the example embodiment of FIG. 17, the mold layer 170 may be formed on the etch stop layer 168. The mold layer 170 may be used to form the storage electrodes 176 of the capacitors 182. Because heights of the storage node electrodes 176 may based on a thickness of the mold layer 170, a thickness of the mold layer 170 may be adjusted to obtain a desired capacitance of the capacitors 182.

In the example embodiment of FIG. 17, a third mask film may be formed on the mold layer 170. The third mask film may include a material having an etching selectivity with respect to the mold layer 170. In an example, the third mask film may include silicon nitride. In a further example, the third mask film may be substantially thicker than the etch stop layer 168.

In the example embodiment of FIG. 17, fifth photoresist patterns may be formed on the third mask film. The third mask film may be anisotropically etched using the fifth photoresist patterns as an etch mask such that storage node mask patterns 172 may be formed on the mold layer 170.

In the example embodiment of FIG. 17, the fifth photoresist pattern is etched. Thereafter, the mold layer 170, the etch stop layer 168 and the fifth insulation interlayer 166 may be anisotropically etched using the storage node mask patterns 172 as an etch mask such that openings 174 exposing the storage node contact plugs 164 may be formed.

FIG. 18 is a cross-sectional view illustrating the capacitors 182 formed on the storage node contact plugs 164 of FIG. 17 according to another example embodiment of the present invention.

In the example embodiment of FIG. 18, a fifth conductive layer may be formed on the storage node contact plugs 164 and side faces of the openings 174. In an example, the fifth conductive layer may include polysilicon doped with impurities. In another example, the fifth conductive layer may include metal nitride (e.g., titanium nitride).

In the example embodiment of FIG. 18, a sacrificial layer may be formed on the fifth conductive layer to further fill the openings 174 that may be partially filled with the fifth conductive layer. In an example, the sacrificial layer may include substantially the same material as the mold layer 170.

In the example embodiment of FIG. 18, after the sacrificial layer is formed, upper portions of the sacrificial layer and the fifth conductive layer may be removed until the storage node mask patterns 172 are exposed such that storage node electrodes 176 having cylindrical shapes may be formed in the openings 174. In an example, the upper portions of the sacrificial layer and the fifth conductive layer may be removed by a CMP process. The sacrificial layer may function to protect the storage node electrodes 176 in the CMP process.

In the example embodiment of FIG. 18, after the storage node electrodes 176 are formed, the storage node mask pattern 172, the mold layer 170 and the sacrificial layer may be removed such that the storage node electrodes 176 may be exposed. The storage node mask pattern 172 may be removed using an etching solution (e.g., including phosphoric acid). The mold layer 170 and the sacrificial layer may be removed using a limulus amebocyte lysate (LAL) solution, a standard clean 1 (SC1) solution and/or a diluted fluoride solution. In an example referring to the diluted fluoride solution, a ratio of water to fluoride may be about 100:1 to about 400:1. The LAL solution may include ammonium fluoride, hydrogen fluoride and water. The SC1 solution may include ammonium hydroxide, hydrogen peroxide and water. In yet another example, the SC1 solution may be a common cleaning solution used in conventional semiconductor manufacturing processes. In an alternative example, the mold layer 170 and the sacrificial layer may be removed by a dry etch process using an etching gas (e.g., including fluoride).

In the example embodiment of FIG. 18, a dielectric layer 178 and a plate electrode 180 may be formed on the storage node electrodes 176 and the etch stop layer 168 such that the capacitors 182 electrically connected to the storage node contact plugs 164 may be manufactured. In an example, the dielectric layer 178 may include silicon oxide and/or silicon oxynitride. In an alternative example, the dielectric layer 178 may include material having a relatively large dielectric constant, such as one or more of hafnium oxide (HfO₂), zirconium oxide (ZrO₂), zircon (ZrSiO), lanthanum oxide (La₂O₃), tantalum oxide (Ta₂O₅), titanium dioxide (TiO₂), strontium titanate (SrTiO₃) or barium-strontium titanate ((Ba,Sr)TiO).

In another example embodiment of the present invention, while not illustrated in the Figures, it is understood that if the storage node electrodes 176 and the storage node contact plugs 164 include titanium nitride and polysilicon doped with impurities, respectively, a metal silicide layer may be further formed on the storage node contact plugs 164. The metal silicide layer may operate as an ohmic layer reducing an ohmic resistance. In an example, the metal silicide layer may include titanium silicide layer. If the storage node electrodes 176 and the storage node contact plugs 164 include titanium nitride and metal (e.g., tungsten), respectively, a titanium layer may be further formed on the storage node contact plugs 164 and the side faces of the openings 174 before the fifth conductive layer may be formed.

As described in the above example embodiments of the present invention, the capacitors 182 formed on the storage node contact plugs 164 may be embodied as cylindrical capacitors. However, in an alternative example embodiment of the present invention, while not illustrated in the Figures, stack-typed capacitors may be formed on the storage node contact plugs 164 in place of the cylindrical capacitors. Further, other example embodiments of the present invention may be directed to other well-known types of capacitors having any shape.

In another example embodiment of the present invention, bit line masks may be used to form bit lines. Thereafter, the bit line masks may be removed. Accordingly, aspect ratios of spaces between the bit lines may be reduced as compared to bit lines formed in accordance with conventional methodologies. Further, fewer voids or gaps may generated in an insulation layer filling (e.g., at least partially) the spaces. Furthermore, voids may be formed in a capping layer to expose contact pads via an etch-back process using the voids. Accordingly, the contact pads may be exposed without a conventional storage node contact mask. Furthermore, conventional bit line spacers need not be formed on side faces of the bit lines, aspect ratios of the spaces between the bit lines may thereby be reduced. Consequently, contact plugs electrically connected to the contact pads may be electrically insulated from the bit lines by the capping patterns formed on the bit lines. In addition, the contact plugs may be electrically insulated from one another by insulation layer patterns. Furthermore, the contacts plugs may be efficiently guided (e.g., in contact with) toward the contact pads.

Further, in another example embodiment of the present invention, unlike conventional bit line spacers including silicon nitride, the capping layer may include silicon oxide. A parasite capacitance may thereby be reduced or suppressed between bit lines and storage node contact plugs.

Example embodiments of the present invention being thus described, it will be obvious that the same may be varied in many ways. For example, while the above-described example embodiments of the present invention are directed generally to

Such variations are not to be regarded as departure from the spirit and scope of example embodiments of the present invention, and all such modifications as would be obvious to one skilled in the art are intended to be included within the scope of the following claims.

What is claimed is:

1. A semiconductor device, comprising:
a semiconductor structure including first contact pads and second contact pads;
an insulation interlayer formed on the semiconductor structure, the insulation interlayer including first contact holes exposing the first contact pads and second contact holes exposing the second contact pads;
conductive patterns formed on the first insulation interlayer, the conductive patterns extending in a first direction and being electrically connected to the first pads through the first contact holes;
insulation layer patterns formed on an upper face of the insulation interlayer and the conductive patterns, the insulation layer patterns extending in a second direction other than the first direction;
capping patterns formed on portions of the conductive patterns and side faces of the second contact holes, the portions being positioned between the insulation layer patterns; and
contact plugs formed between the capping patterns, the contact plugs being electrically connected to the second contact pads.

2. The semiconductor device of claim 1, wherein the capping patterns include at least one of tetraethyl orthosilicate and undoped silicate glass.

3. The semiconductor device of claim 1, wherein the capping patterns include silicon oxide obtained by at least one of a higher density plasma chemical vapor deposition process and a plasma enhanced chemical vapor deposition process.

4. The semiconductor device of claim 1, wherein the semiconductor structure further includes at least one transistor electrically connected to the first and second contact pads.

5. The semiconductor device of claim 1, further comprising:
at least one capacitor formed on the contact plugs.

6. A method of manufacturing a semiconductor device, comprising:
forming a semiconductor structure including first contact pads and second contact pads;
forming an insulation interlayer on the semiconductor structure, the insulation interlayer including first contact holes exposing the first contact pads;
forming conductive patterns on the insulation interlayer, the conductive patterns extending in a first direction and being electrically connected to the first contact pads through the first contact holes;
forming insulation layer patterns on an upper face of the insulation interlayer and the conductive patterns, the insulation layer patterns extending in a second direction other than the first direction;
anisotropically etching first portions of the insulation layers to form second contact holes exposing the second contact pads, the first portions being exposed between the conductive patterns and the insulation layer patterns;
forming capping patterns on second portions of the insulation layer patterns and side faces of the second contact holes, the second portions being exposed between the insulation layer patterns; and
forming contact plugs between the capping patterns, the contact plugs electrically connected to the second contact pads.

7. The method of claim 6, wherein forming the insulation layer patterns includes
forming a second insulation interlayer on the conductive patterns and the insulation interlayer,
forming mask patterns on the second insulation interlayer, the mask patterns extending in the second direction, and
performing an anisotropic etching process using the mask patterns as an etch mask to obtain the insulation layer patterns.

8. The method of claim 7, wherein forming the insulation layer patterns further includes planarizing the second insulation interlayer.

9. The method of claim 7, wherein forming the insulation layer patterns further includes:
planarizing the second insulation interlayer at least until the conductive patterns are exposed, and
forming a third insulation interlayer pattern on the second insulation interlayer, and
wherein the second insulation interlayer and the third insulation layer patterns are anisotropically etched using the mask patterns as an etching mask to obtain the insulation layer patterns.

10. The method of claim 7, wherein the second contact holes are formed by an anisotropic etching process that uses the mask patterns as an etching mask.

11. The method of claim 6, wherein forming the conductive patterns include
forming a conductive layer on the insulation interlayer,
forming at least one mask pattern on the conductive layer, the at least one mask pattern extending in the first direction;
anisotropically etching the conductive layer by using the at least one mask pattern as an etching mask to obtain the conductive patterns; and
removing the at least one mask pattern.

12. The method of claim 6, wherein forming the capping patterns includes
forming a capping layer on the second contact pads, side faces of the second contact holes, the conductive patterns and the insulation layer patterns to generate voids in the second contact holes in spaces between the conductive patterns and the insulation layer patterns; and
performing an etch-back process on the capping layer to open the voids and expose the second contact pads.

13. The method of claim 12, wherein the capping layer includes at least one of tetraethyl orthosilicate and undoped silicate glass.

14. The method of claim 6, wherein forming the semiconductor structure includes
defining active regions electrically insulated from one another by an isolation layer formed at an upper portion of a semiconductor substrate,
forming gate structures in the active regions,
forming first impurity regions and second impurity regions at surface portions of the active regions, the surface portions being adjacent to the gate structures, the first impurity regions and the second impurity regions operating as source/drain regions, and
forming the first contact pads and the second contact pads on the first impurity regions and the second impurity regions.

15. The method of claim 6, further comprising:
forming capacitors on the contact plugs.

16. A method of manufacturing a semiconductor device, comprising:
forming a plurality of bit lines;
forming a capping layer on the plurality of bit lines, the capping layer selectively including at least one void between adjacent bit lines of the plurality of bit lines; and
removing a portion of the capping layer, the removed portion including the at least one void.

17. The method of claim 16, further comprising:
filling, at least in part, the removed portion of the capping layer with a conductive layer; and
planarizing remaining portions of the capping layer and the conductive layer.

18. The method of claim 16, wherein the capping layer includes a material with a relatively poor step coverage so as to form the at least one void.

19. The method of claim 16, wherein removing the portion of the capping layer is performed with an etch-back process.

20. A method of manufacturing a semiconductor device, comprising:
forming a plurality of bit lines based on a plurality of bit mask patterns; and
removing, at least in part, the plurality of bit mask patterns after forming the plurality of bit lines.

21. A semiconductor device formed with the method of claim 6.

22. A semiconductor device formed with the method of claim 16.

23. A semiconductor device including a plurality of bit lines formed with the method of claim 20.
